(19) United States
(12) Patent Application Publication
(10) Pub. No.: US 2006/0261390 A1
(43) Pub. Date: Nov. 23, 2006

(54) Dynamic random access memory integrated element

(75) Inventor: Pierre Malinge, Saint Martin D'uriage (FR)

Correspondence Address: JENKENS & GILCHRIST, PC, 1445 ROSS AVENUE, SUITE 3200, DALLAS, TX, 75202, US

(73) Assignee: STMicroelectronics S.A., Montrouge (FR)

(21) Appl. No.: 11/398,855

(22) Filed: Apr. 6, 2006

(30) Foreign Application Priority Data
Apr. 28, 2005 (FR) 0504317

(51) Int. Cl. H01L 29/94

(52) U.S. Cl. 257/296

(57) ABSTRACT

A dynamic random access memory integrated element includes a transistor and a region for the storage of electrical charges. The surface area of an electrical junction between a source region of the transistor and the storage region is smaller than the surface area of an electrical junction between a drain region of the transistor and the storage region. Such a memory element can be fabricated from a standard substrate using SOI technology or from a bulk silicon substrate, and a bit stored in the element can be erased with reduced power consumption.

### PRIORITY CLAIM

The present application claims priority from French Patent Application No. 05 04317 filed Apr. 28, 2005, the disclosure of which is hereby incorporated by reference.

### BACKGROUND OF THE INVENTION

1. Technical Field of the Invention

The present invention relates to a dynamic random access memory, or DRAM, integrated element. It also relates to a process for erasing a bit stored in the memory element, together with a memory array comprising such elements.

2. Description of Related Art

Certain DRAM elements are composed of one access transistor and of one capacitor. The storage of a bit in such an element is associated with a quantity of electrical charge contained within the capacitor. When the quantity of electrical charge contained within the capacitor is greater than a given threshold, the stored bit is equal to 1. Conversely, the stored bit is equal to 0 when the quantity of electrical charge contained within the capacitor is less than the given threshold. However, a memory composed of such elements is costly to produce, owing notably to the fabrication steps required to form the capacitors of the DRAM elements.

In order to reduce the cost of the memory and to increase its level of integration, new DRAM elements have been proposed which do not comprise capacitors. Such memory elements only comprise an MOS (Metal-Oxide-Semiconductor) transistor which incorporates a central region of semiconductor material itself capable of storing a certain quantity of electrical charge. In other words, the transistor itself can contain a variable quantity of electrical charge which is associated with the stored binary value. These new memory elements are referred to as capacitor-less DRAM elements.

FIGS. 1a and 1b show a section of such a capacitor-less DRAM element, and respectively illustrate a step for writing a bit and a step for erasing the written bit. A semiconductor substrate of the capacitor-less DRAM element has a substantially planar surface S. D2 denotes a direction perpendicular to the surface S. The reference 100 denotes a lower conducting part of the substrate, which can be maintained at a reference electrical potential, by convention equal to 0 V (volt), or at ground. The lower part of the substrate 100 is coated with a layer 101 of electrically insulating material, for example silica (SiO2), and with a layer 102 of semiconductor silicon. Such a substrate with layers 101 and 102 is employed in the integrated circuit fabrication technology denoted by SOI (standing for ‘Silicon-On-Isolator’).

The MOS transistor of the capacitor-less DRAM element is denoted overall by the reference 10. It comprises the following elements: a source region 1 and a drain region 2; a region 5 for storing electrical charges running between the regions 1 and 2 in a direction D1 parallel to the surface S. The region 5 may also be referred to as floating substrate, by analogy with MOS transistor fabrication technology on bulk silicon; and a gate region 3 disposed above the surface S and separated from the region 5 by a gate insulation layer 4.

The regions 1 and 2 are n-doped and the region 5 is p-doped. They are disposed within the layer 102 and isolated electrically from the lower part of the substrate 100 by the layer 101.

FIGS. 1c and 1d show two sections of such a capacitor-less DRAM element, in respective planes perpendicular to the direction D1. The cross-sectional plane of FIG. 1c cuts the transistor 10 across the region 5, and the cross-sectional plane of FIG. 1d cuts the transistor 10 across the region 1 or across the region 2. The regions 1, 2 and 5 are surrounded by a lateral barrier 103 of insulating material, whose thickness in the direction D2 is equal to the thickness of the layer 102 within which the regions 1, 2 and 5 are formed.

For the MOS transistor fabrication technology denoted by 120 nm (nanometers), the layer 4 can have a thickness in the direction D2 in the range from 1.5 nm to 6.5 nm, and the length of the transistor, in other words the distance between the regions 1 and 2 in the direction DI, can be in the range from 120 nm to 280 nm. These dimensions may be smaller for later MOS transistor fabrication technologies.

The layer 102 has a thickness in the range from 20 nm to 150 nm. This thickness is such that a region depleted of electrical carriers generated by the gate region 3 in the region 5 does not extend as far as the layer 101. The substrate is then referred to as a partially-depleted SOI substrate by those skilled in the art.

In operation, such a capacitor-less DRAM element can exhibit two distinct states that respectively correspond to a stored binary value equal to 1 or to 0. These two states are respectively associated with quantities of positive and negative electrical charge contained within the region 5.

In order to write the value 1 into the capacitor-less DRAM element (FIG. 1a), an electrical current is generated from the drain region 2 towards the source region 1. For this purpose, the following electrical potentials are respectively applied to the source region 1, to the drain region 2 and to the gate region 3: around 0 V, 2.5 V and 1.0 V, respectively. The transistor 10 is then in an electrically conducting state: a high current of electrons, denoted e⁻ in FIG. 1a, flows from the source region 1 towards the drain region 2, through a portion of the region 5 situated against the gate insulation layer 4. This conducting portion of the region 5 forms a conduction path between the regions 1 and 2: this constitutes the channel of the transistor 10, referenced 6. This flow of electrons causes, by collisions occurring at the end of the channel 6 close to the junction between the regions 5 and 2, the formation of electron-hole pairs. This phenomenon is called impact ionization. The electrons e⁻ created by the collisions are evacuated via the drain region 2, and the holes h⁺ accumulate in the region 5 close to the respective junctions of the region 5 with the regions 1 and 2, and close to the layer 101. These locations where the holes accumulate form the space-charge region. The holes h⁺ are held within the region 5 by the positive electrical potential barrier, of around 0.6 V, of the electrical junction between the region 5 and the source region 1, on the one hand, and between the region 5 and the drain region 2, on the other. A sufficient quantity of holes that is thus contained within the region 5 corresponds to the storage of the binary value 1 in the capacitor-less DRAM element.

In order to erase this stored binary value 1 (FIG. 1b), the transistor 10 is brought into a reverse-biased state: the source region 1 is set at 0 V, the drain region 2 is set at −1.5 V and the gate region 3 is set at a potential of around 1.0 V. The holes h⁺ are thus evacuated by the drain region 2. But, during this erase step, the transistor 10 is again in an electrically conducting state. A significant electrical current, denoted I in FIG. 1b, then flows from the source region 1 towards the drain region 2. The result of this is a high power consumption during the erase operation of the stored bit.

A reduction in this power consumption during the erase operation could be obtained by reducing the electrical potential applied to the gate region 3, so as to prevent the formation of a channel in the region 5 and thus turn off the transistor 10. For example, the gate region 3 could be set at 0 V, instead of 1.0 V, during erasure of the stored bit. But the holes h⁺ are not then properly evacuated to the drain region 2, owing to the electrostatic interaction present between the storage region 5 and the source region 1. At the end of the erase step, a residual quantity of holes h⁺ still remains in the storage region 5, such that the erasing of the bit is incomplete.

Whatever the erase mode implemented, by turning on or off the transistor 10, the amplitude of variation obtained for the quantity of electrical charge contained in the region 5 is insufficient. In other words, the quantities of electrical charge respectively corresponding to the binary values 1 and 0 are not sufficiently differentiated. An MOS transistor fabricated in the usual manner cannot therefore be used as a capacitor-less DRAM element.

In order to overcome this difficulty, a proposed solution is to stabilize the electrical potential in the region 5 by associating an additional electrode with the transistor 10. Erasing the binary value 1 can then be facilitated, and the capacity for retention of a quantity of electrical charge in the region 5 can be enhanced (see, for example, T. Ohsawa et al., “Memory Design Using a One-Transistor Gain Cell on SOI,” IEEE JSSC 2002, vol. 37, no 11, pp. 1510-1522, November 2002). According to a first proposed configuration, protrusions of the part 100 of the substrate are situated on either side of the storage region 5. However, the transistor 10 then becomes particularly complex to fabricate. According to a second proposed configuration, the isolation layer 101 is very thin with a thickness of around 25 nm. Such a thickness does not correspond to that of the standard SOI process, for which the thickness of the layer 101 is in the range from 200 to 500 nm. A special substrate, which is not yet commercially available, is therefore required in order to produce capacitor-less DRAM elements having the second configuration proposed. Furthermore, such capacitor-less DRAM elements still have a high power consumption, since the transistor is turned on during the erase operation.

There is a need in the art for a capacitor-less DRAM element configuration that does not have the aforementioned drawbacks.

### SUMMARY OF THE INVENTION

An embodiment of the invention provides a dynamic random access memory integrated element designed to store one bit, which comprises an MOS transistor disposed on the surface of a substantially planar substrate. The transistor comprises: a source region and a drain region separated from one another and having a doping of a first type; a region for the storage of electrical charges running between the source and the drain regions in a first direction parallel to the substrate surface, and having a doping of a second type opposite to the first type; and a gate region running above the storage region and being isolated from the storage region by an insulating layer.

The source, drain and storage regions are electrically separated from a lower conducting part of the substrate. Furthermore, an electrical junction surface area between the source region and the storage region is smaller than an electrical junction surface area between the drain region and the storage region. In this way, the electrostatic influence exerted by the source region on electrical charges contained in the storage region is reduced, with respect to the electrostatic influence exerted by the drain region on these electrical charges. A bit stored in such a DRAM element can then be erased by applying an electrical potential equal to zero to the substrate, to the source region and to the gate region of the transistor, and in simultaneously applying to the drain region an electrical potential designed to repel electrical charges contained in the storage region. The electrical charges contained in the storage region can thus be evacuated efficiently via the source region.

A memory element according to the invention can therefore be used as capacitor-less DRAM element, in the previously-defined sense.

During the operation to erase a binary value stored in a DRAM element according to the invention, the electrical potentials of the source, drain and gate regions can be such that the transistor is held in the off state. The conduction current between the drain region and the source region, via the storage region, is then zero. A source for supplying power to the DRAM element does not therefore deliver any power when a bit is erased. This results in a significant reduction in the power consumption of the DRAM element.

Preferably, the surface area of the electrical junction between the source region and the storage region is smaller than the surface area of the electrical junction between the drain region and the storage region by a factor greater than 1.5. In this case, the electrostatic influence exerted by the drain region on electrical charges contained in the storage region is completely dominant, such that the electrical charges can be evacuated even more efficiently in order to erase the stored bit.

Advantageously, a width of the electrical junction between the source region and the storage region is shorter than a width of the electrical junction between the drain region and the storage region, the widths being measured in a direction parallel to the substrate surface and perpendicular to the first direction. In this case, the two source and drain junctions can have the same thickness in the direction perpendicular to the substrate surface, such that the structure of the DRAM element is simplified.

According to one embodiment of the invention, the electrical junction between the source region and the storage region and the electrical junction between the drain region and the storage region can each be substantially planar. The DRAM element then has an even simpler structure.

According to other embodiments of the invention, the junction between the source region and the storage region can again be substantially planar, whereas the junction between the drain region and the storage region can have at least one variation in orientation between several points of this junction. This variation in orientation of the junction between the drain region and the storage region increases the effective width of this junction. In this case, in order to obtain a good control of the conduction state of the transistor, the gate region can have a cross section, in a plane parallel to the substrate surface, having a contour that overlays, on the side of the drain region, a projection of the electrical junction between the drain region and the storage region.

A DRAM element according to the invention can be fabricated from a substrate using SOI technology. In this case, the DRAM element additionally comprises a buried electrically insulating layer that is disposed between the source, drain and storage regions, on the one hand, and the lower conducting part of the substrate, on the other, in a second direction perpendicular to the substrate surface. This buried insulating layer forms the electrical separation between the source, drain and storage regions and the lower conducting part of the substrate. It can have a thickness in the range between 25 and 400 nanometers in the second direction. Such a thickness corresponds to a standard substrate used in SOI technology.

The DRAM element can then additionally comprise a lateral barrier of insulating material disposed within the substrate on either side of the transistor in a direction parallel to the substrate surface. This barrier extends in depth into the substrate at least as far as the buried electrical insulating layer.

Such a DRAM element with buried insulating layer can be designed such that, during operation of the element, the storage region has a depletion region that is thinner, in the second direction, than the storage region itself. For this purpose, the thickness of the storage region can be chosen appropriately, or a counter-electrode can be disposed within the lower part of the substrate, so as to exert an electrostatic influence on electrical charges contained in the storage volume.

Alternatively, a DRAM element according to the invention can be fabricated from a bulk silicon substrate. No electrical insulating layer then separates the source, drain and storage regions of the transistor from the lower conducting part of the substrate. The electrical separation can be formed by a buried electrical junction disposed between the source, drain and storage regions, on the one hand, and the lower conducting part of the substrate, on the other, in the second direction perpendicular to the substrate surface.

In order to electrically isolate the DRAM element from other electronic components disposed on the same substrate, the DRAM element can also comprise a lateral barrier of insulating material disposed within the substrate on either side of the transistor in a direction parallel to the substrate surface. This lateral barrier then extends depth-wise into the substrate at least as far as the buried electrical junction.

The buried electrical junction can be formed between the storage region and a buried semiconductor region having a doping of the first type, at a depth in the substrate situated beyond the limits of the source and drain regions on a side opposite to the substrate surface. The DRAM element may also comprise means for applying an electrical bias potential to the buried semiconductor region, designed to keep the buried electrical junction in a non-conducting state.

The invention also provides a process for erasing a bit stored in a dynamic random access memory integrated element such as was previously described. According to this process, the source region, the drain region and the gate region have respective electrical potentials designed so that the drain region exerts a repulsive force on electrical charges contained in the storage volume in order to evacuate the charges via the source region, and such that the transistor is simultaneously in an off state. Preferably, the absolute difference between the respective electrical potentials of the drain region and of the source region is greater than or equal to 1.2 V at one given moment at least during the erase operation. The erasing of the bit stored in the DRAM element then happens rapidly and is complete.

The invention lastly relates to a memory array comprising capacitor-less DRAM elements, such as previously described, disposed according to a matrix configuration on the surface of a substrate common to these elements.

Finally, the invention relates to a process for erasing a word stored in such a memory array, according to which a first and a second electrical potential are respectively applied to the source line and to the word line assigned to a row of memory elements containing the stored word, the first and second electrical potentials being chosen so as to put each memory element transistor of the row into an off state, and according to which a third electrical potential is applied to all of the bit lines such that the first and third electrical potentials cause, within each memory element of the row, an evacuation of charges present in the storage region towards the source region.

In accordance with an embodiment, a dynamic random access memory integrated transistor element, comprises a source region and a drain region separated from each other by a charge storage region, the source region and charge storage region forming a first electrical junction and the drain region and charge storage region forming a second electrical junction, and wherein a surface area of the first electrical junction is smaller than a surface area of the second electrical junction.

### BRIEF DESCRIPTION OF THE DRAWINGS

Other characteristics and advantages of the invention will become further apparent on reading the description which follows. The latter is purely illustrative and should be read in conjunction with the appended drawings, in which:

FIGS. 1a and 1b, already described above, respectively illustrate steps for writing and erasing a bit in a capacitor-less DRAM element according to the prior art;

FIGS. 1c and 1d, already described above, are cross sections of a capacitor-less DRAM element such as is considered in FIGS. 1a and 1b;

FIGS. 2a to 2d are respective top views of DRAM elements according to the invention, for four different embodiments;

FIG. 3 illustrates a step for erasing a bit stored in a DRAM element according to the invention;

FIG. 4 illustrates variations of a quantity of electrical charge contained in a DRAM element according to FIG. 2d;

FIG. 5 is a connection diagram of a memory array comprising DRAM elements according to the invention;

FIGS. 6a and 6b are top views of memory arrays comprising DRAM elements according to the invention; and

FIG. 7 illustrates another type of design of DRAM elements according to the invention.

### DETAILED DESCRIPTION OF THE DRAWINGS

In these figures, identical references denote elements that are identical, or that have an identical function. In addition, the dimensions of the transistor parts shown are not in proportion to real dimensions. In particular, dimensions in different directions are not necessarily reproduced with the same scaling factor.

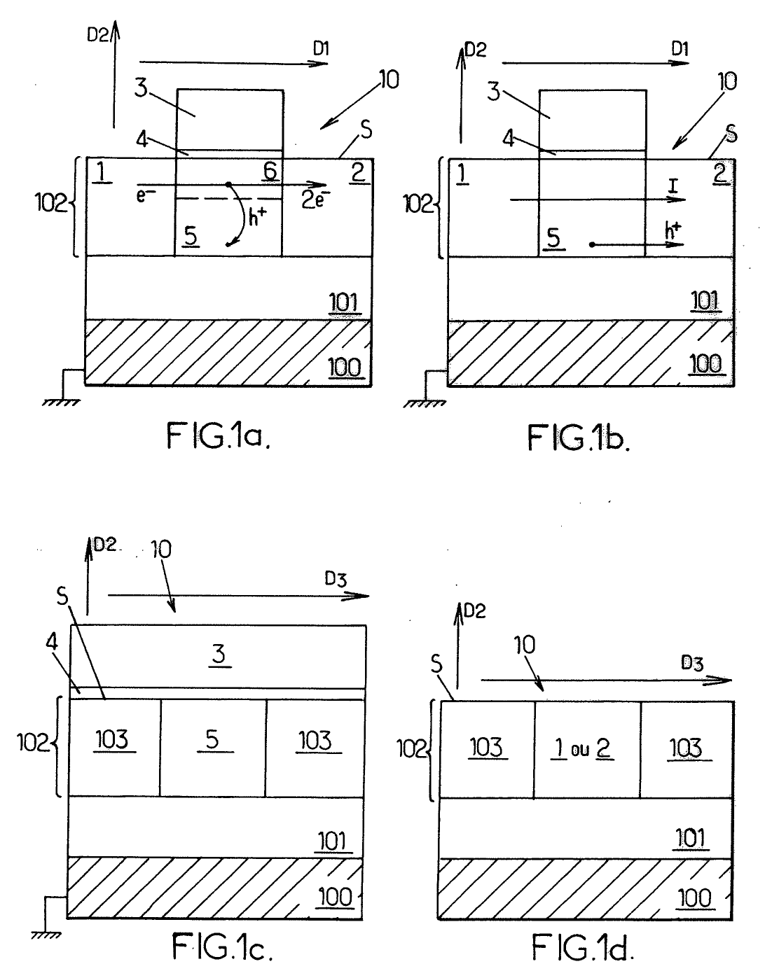

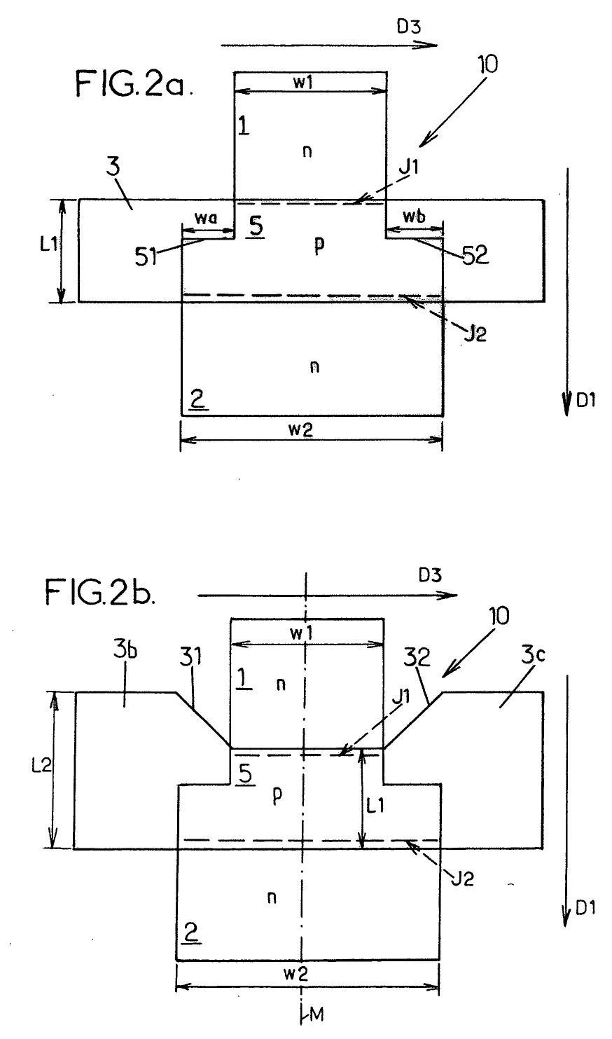

A DRAM element according to the invention can be fabricated by SOI integrated electronic circuit fabrication technology. The DRAM element therefore has a structure for which one cross section in a plane perpendicular to the surface of the substrate is analogous to that shown in FIG. 1a. The layer 101 is a layer of silica (SiO₂), which advantageously has a thickness that may be in the range between 200 and 500 nm in the direction D2, perpendicular to the substrate surface S. It electrically isolates a layer of semiconductor silicon 102 from a lower conducting part 100 of the substrate. The thickness of the layer of silicon 102, in which the source 1, hole storage 5 and drain 2 regions are formed can, for example, be 1 μm (micrometer) in the direction D2. In the exemplary embodiments of the invention which are described in the following, the regions 1 and 2 are n-doped, and the region 5 is p-doped. In other words, the transistor 10 is of the n-MOS type.

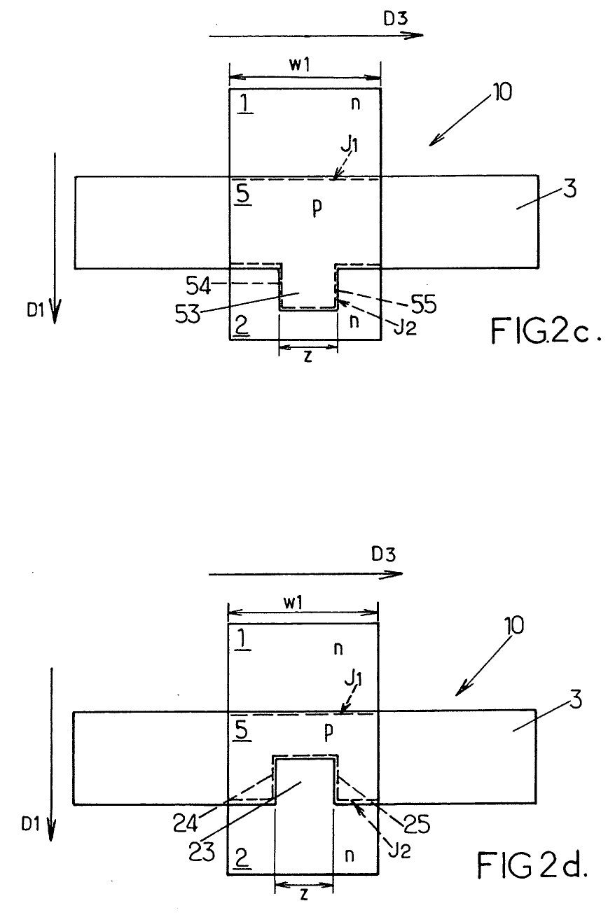

According to a first embodiment of the invention, the two junctions J1 and J2, respectively between the regions 1 and 5 and between the regions 2 and 5, are planar and oriented perpendicularly to the direction D1. FIG. 2a is a top view of such a DRAM element, in a direction of observation parallel to the direction D2 but in the opposite sense. In order to improve the clarity of FIG. 2a, the n or p type dopings of the regions 1 and 2 and 5 are indicated. A projection of the storage region 5 in the plane of the figure has two rectilinear sides, against the source 1 and drain 2 regions respectively, and two lateral shoulders 51 and 52. The region 5 has a first width w1 on the side of the source region 1, in a direction D3 perpendicular to the direction D1 and contained in a plane parallel to the substrate surface S, and a second width w2, greater than w1, on the side of the drain region 2. In this case, w1 and w2 are therefore substantially equal to the respective widths of the junctions J1 and J2. Further, wa and wb respectively denote the widths of the shoulders 51 and 52 in the direction D3. By way of illustration, when a 0.13 μm MOS transistor fabrication technology is used, wa and wb can be equal to around 0.28 μm. When the two shoulders 51 and 52 of the region 5 have identical widths, in other words when wa=wb, the projection of the region 5 in a plane parallel to the surface S takes the form of a T. In FIG. 2a, this T form is inverted from top to bottom.

If the region 5 only has a shoulder on one side (wa=0 for example), the projection of the region 5 in a plane parallel to the surface S takes the form of an L. Similarly, a trapezoidal form is obtained when the two shoulders 51 and 52 are oriented obliquely with respect to the directions D1 and D3.

According to FIG. 2a, a projection of the gate region 3 of the DRAM element in a plane parallel to the surface S takes the form of a rectangle. L1 denotes the length of the gate region 3 in a direction parallel to the direction D1.

FIG. 2b illustrates an improvement of the DRAM element in FIG. 2a. The regions 1, 2 and 5 are identical to those just described. The projection of the gate region 3 of the DRAM element in a plane parallel to the surface S now exhibits a butterfly shape. Here, the gate region 3 has a central part 3a of substantially the same dimensions as the storage region 5, in a direction parallel to the surface S. It also has two lateral parts 3b and 3c situated on either side of a medial plane M perpendicular to the direction D3 and cutting the regions 1 and 2. The lateral parts 3b and 3c of the gate region 3 have the same length L2 in the direction D1, which is greater than the length L1 of the central part 3a. The respective lengths of the two lateral parts 3b and 3c may be different, where required. First respective sides of the central part 3a and of each of the lateral parts 3b and 3c of the gate region, on the side of the drain region 2, are aligned. In addition, second respective sides of the parts 3a, 3b and 3c of the gate region, on the side of the source region 1, are connected via intermediate sloping faces 31 and 32. In this way, an unintentional displacement of the gate region 3 with respect to the region 5, in a direction parallel to the direction D1 and in the direction of the drain region 2, only produces a gradual reduction in the control of the conduction state of the electrical junction J1 by the gate region 3. The unusual form of the region 5 in this first embodiment of the invention does not then cause an abrupt decrease in a fabrication yield of the DRAM element.

FIG. 2c corresponds to FIG. 2a for a second embodiment of a DRAM element according to the invention. The electrical junction J1, between the source region 1 and the storage region 5, is again planar. The electrical junction J2, between the drain region 2 and the storage region 5, takes the form of a turret, such that the orientation of a plane tangent to the junction J2 varies as it moves through the junction. According to FIG. 2c, the region 5 has a protrusion 53 that penetrates into the drain region 2. The protrusion 53 has a width z less than the width w1 of a main part of the region 5. The widths z and w1 are measured in the direction D3. The effective width w2 of the junction J2 is then equal to the sum of the width w1 and of the two lengths of the lateral sides 54 and 55 of the protrusion 53 in the direction D1. It is therefore greater than the width of the junction J1, which is substantially equal to w1. By way of example, the lengths of the sides 54 and 55 of the protrusion 53, in the direction DI, can be equal to 0.13 μm.

According to a third embodiment of the invention illustrated by FIG. 2d, the junction J2 again takes the form of a turret, but this one is formed by a protrusion 23 from the drain region 2 that penetrates into the storage region 5. By analogy with the second embodiment, z and w1 again respectively denote the width of the turret and the width of the region 5 in the direction D3. z is less than w1. The width of the junction J1 is again substantially equal to w1, and the effective width w2 of the junction J2 is equal to the sum of w1 and of the lengths of the lateral sides 24 and 25 of the protrusion 23. The lengths of the sides 24 and 25 of the protrusion 23, in the direction D1, can be equal to 0.13 μm, for example.

In the preceding second and third embodiments, respectively illustrated by FIGS. 2c and 2d, it is advantageous that the gate region 3 has a cross section, in a plane parallel to the substrate surface S, having a contour that substantially overlays, on the side of the drain region 2, a projection of the turret of the electrical junction J2. The conduction state of the electrical junction J2 is then well controlled by an electrical potential applied to the gate region 3.

The writing of a bit into a DRAM element according to one of the embodiments described above can be performed in the same manner as for a capacitor-less DRAM element of the prior art (see FIG. 1a). Potentials of, for example, 0 V and 1 V are respectively applied to the source 1 and gate 3 regions. Since the difference between the electrical potentials of the regions 3 and 1 is greater than the threshold voltage of the transistor, which is in general in the range between 0.2 V and 0.8 V, the transistor 10 is turned on. If a positive electrical potential is applied at the same time to the drain region 2, for example an electrical potential of around 2.5 V, an electron current flows from the region 1 towards the region 2, which generates holes h⁺ by collisions with the atoms of the region 5. These holes h⁺ form the quantity of electrical charge which is contained within the region 5 in order to store the binary value 1. If a low electrical potential, for example in the range between 0 V and 1.2 V, is applied to the drain region 2 when the transistor 10 is on, no electron current flows from the region 1 towards the region 2 so as to create a large quantity of holes h⁺ within the region 5. The absence of a sufficient quantity of holes within the region 5 corresponds to the binary value 0 written in the DRAM element. Thus, an electrical charge is either generated or not in the storage region 5, depending on the electrical potential applied to the drain region 2 when the transistor 10 is turned on. During the process for writing the value 0, the inventors have observed that the DRAM element can exhibit a residual power consumption if the electrical potential applied to the drain region 2 is higher than 0 V. On the other hand, if the drain region 2 is at a zero potential during the process for writing the value 0, a spurious interaction can occur between neighboring DRAM elements having common connection terminals.

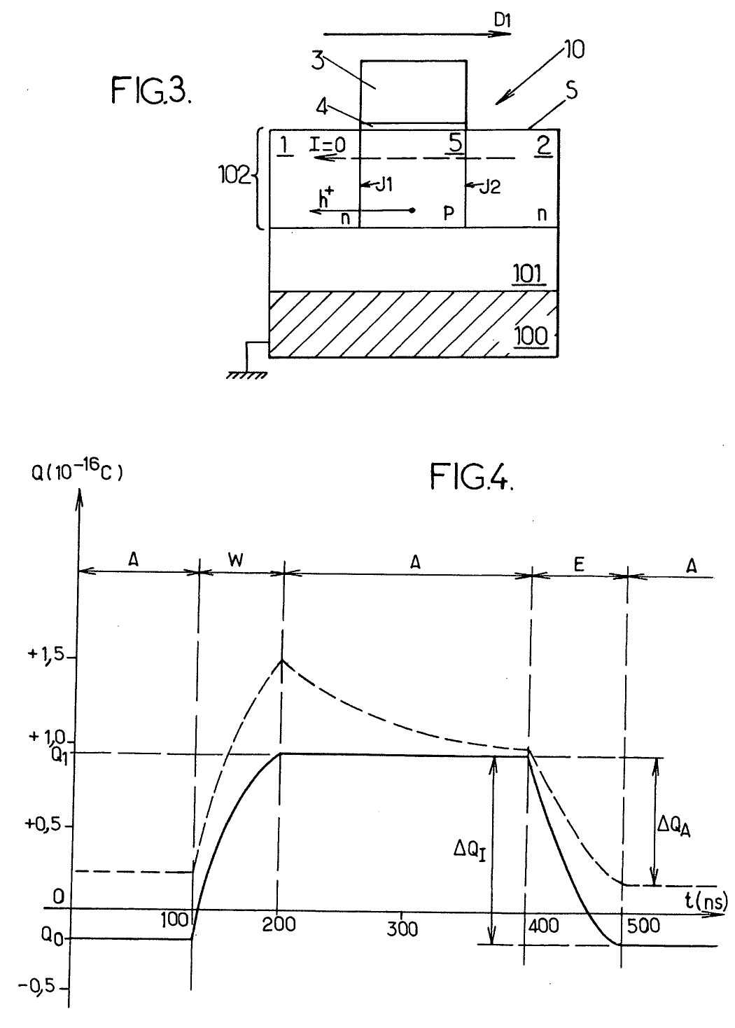

FIG. 3 illustrates the step for erasing a bit stored in a DRAM element according to the invention corresponding to any one of FIGS. 2a-2d. The following electrical potentials are respectively applied to the source 1, drain 2 and gate 3 regions: 0 V, 1.2 V and 0 V. For these values, the electrical potential of the part 100 of the substrate is again taken as reference (equal to 0 V). The combination of a positive value of the electrical potential applied to the drain region 2 with a significant electrostatic influence existing between the drain region 2 and the storage region 5 causes an evacuation of the holes h⁺ contained in the region 5 towards the source region 1. This evacuation is substantial, thanks to the electrostatic repulsion exerted by the drain region 2 on the holes h⁺ present in the storage region 5.

The mode of operation that has just been described for a memory element according to the invention therefore corresponds to that of a capacitor-less DRAM element.

In this mode of operation, the transistor 10 is off during the erase step, given that the difference between the electrical potential of the gate region 3 and that of the source region 2 is less than the threshold voltage of the transistor 10. The current consumption of the DRAM element is therefore negligible during the process for erasing the stored binary value.

Furthermore, it can be noted that an electrical potential higher than 1.2 V applied to the drain region 2, up to 2.5 V, increases the electrostatic repulsion exerted on the holes h⁺ and thus allows the electrical charges present in the region 5 to be evacuated even more efficiently. It will be understood that any other set of values of electrical erase potential which allows evacuation of the holes present in the region 5 towards the source region 1, while at the same time keeping the transistor 10 in an off state, is equally suitable. It should nevertheless be pointed out that the threshold voltage of the transistor can vary as a function of an electrical bias potential applied to the part 100 of the substrate.

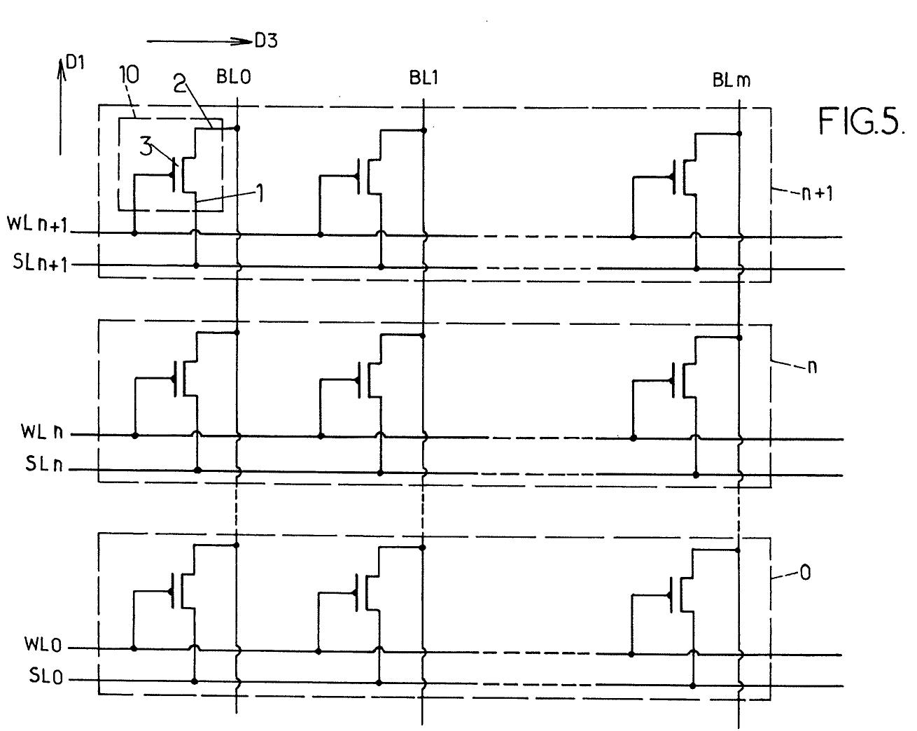

FIG. 4 displays the variations in the quantity of electrical charge contained in the region 5 during an operational cycle of the DRAM element. The horizontal axis shows a time coordinate t, measured in nanoseconds (ns), and the vertical axis indicates the quantity Q of electrical charge contained in the region 5, measured in coulombs (C). It is assumed that the region 5 initially contains no holes. The process then starts with the writing of a binary value equal to 1, lasting around 100 ns (step W for ‘Write’). The next step, denoted A, corresponds to the retention of the stored binary value. It lasts, for example, for 200 ns. The stored value is then erased over a period of 100 ns in the manner described above (phase E for ‘Erase’), then a new retention step takes place, which corresponds to a wait phase before the writing of a new binary value in the DRAM element. The solid curve shows the variations in the quantity of electrical charge for a DRAM element according to the third embodiment of the invention corresponding to FIG. 2d. By way of comparison, the dashed curve indicates the corresponding variations for a capacitor-less DRAM element according to the prior art, in other words with source and drain electrical junctions that have identical dimensions. The values, expressed in volts, of the electrical potentials applied to each DRAM element during the various steps of the operational cycle in FIG. 4 are summarized in the table below:

| | | Writing (W) | | | |
|---|---|---|---|---|---|
| | | of the value | | | |
| | | 1/of the value | | | |
| | | 0 (i.e. non- | A | | R |
| | Step | writing) | (retention) | E (erase) | (read) |
| DRAM | Source (1) | 0 | 1.2 | 0 | 0 |
| element | Drain (2) | 2.5/1.2 or 0 | 1.2 | 1.2 | 0.4 |
| according to | | | | (up to 2.5) | |
| the invention | Gate (3) | 1.0 | 0 | 0 | 0.8 |
| DRAM | Source (1) | 0 | 0 | 0 | 0 |
| element | Drain (2) | 2.5/0 | 0 | −1.5 | 0.4 |
| according to | Gate (3) | 1.0 | −1.0 | 1.0 | 0.8 |
| the prior art | | | | | |

For the two DRAM elements, the electrical potentials applied to the regions 1, 2 and 3 during the retention step are chosen so as to create a potential well within the storage region 5. The electrical charges corresponding to the stored binary value then remain there for a duration longer than one millisecond. Furthermore, a step for reading the stored binary value (table column entitled R for ‘read’) is identical for the two DRAM elements. Such a read step is therefore known to those skilled in the art and is not shown on the graph in FIG. 4.

The following observations can be made, from the curves in FIG. 4, for the DRAM element according to the invention:

at the end of the erase operation, the residual quantity of electrical charge contained within the region 5, denoted Q0, is lower than that obtained with the DRAM element according to the prior art; and

during the retention of the stored binary value 1, the quantity of electrical charge contained within the region 5, denoted Q1, is almost constant for the DRAM element according to the invention, whereas it decreases for the DRAM element of the prior art. The retention of the binary value 1 is therefore superior for the DRAM element of the invention.

The result of this is that the variation, during the erase operation, of the quantity of electrical charge contained within the region 5 is larger, in absolute value, for the DRAM element according to the invention than for the DRAM element of the prior art. This variation, denoted ΔQ_{I}, is approximately −1.2×10⁻¹⁶ C for the DRAM element according to the invention, and −0.8×10⁻¹⁶ C for the DRAM element of the prior art (ΔQ_{A}). The two charge states that respectively correspond to the binary values 0 and 1 are more differentiated from one another for a DRAM element according to the invention than for a capacitor-less DRAM element according to the prior art. In other words, there is a larger read margin.

A correlated effect is that the variation of the electrical potential of the region 5, between the two states that respectively correspond to the binary values 0 and 1, considered just before and just after an erase of the bit, is 0.45 V for the DRAM element of the invention, as compared with ‘0.35 V for the DRAM element of the prior art.

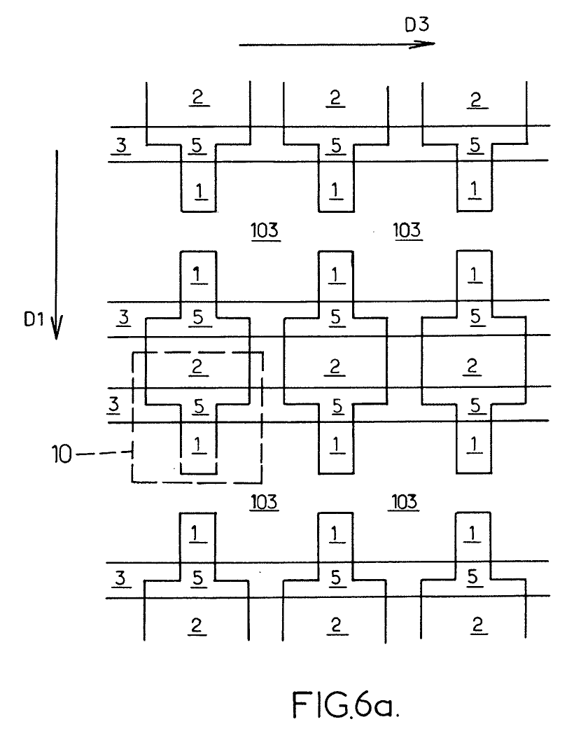

FIG. 5 is an electrical connection diagram of a memory array comprising DRAM elements according to the invention. The DRAM elements are organized in a matrix fashion on the surface of a substantially planar common substrate, according to columns running parallel to the direction D1 and rows running parallel to the direction D3. The DRAM elements of a given row are dedicated to the storage of bits belonging to one and the same word: they are designed to be read or erased at the same time. The references 0, . . . , n and n+1 indicate storage locations of different words, where n is an integer.

The respective gate regions 3 of the transistors 10 of a given row are connected to a word line assigned to this row, denoted WLn for the location of the word n. In parallel, the source regions 1 of the transistors 10 of a given row are connected to a source line assigned to this row, and denoted SLn for the location of the word n. In addition, the drain regions 2 of the transistors 10 of a given row are connected to different bit lines, denoted BL0, BL1, . . . , BLm, where m is an integer, for example equal to 16 or 32. A given bit line is assigned to a single column of transistors 10 in the memory array.

The operation of the memory array is now described. Initially, electrical potentials are respectively applied to the lines of the memory array so as to keep the memory array in a state for retaining the stored words. For this purpose, all the source lines SL0, . . . , SLn, SLn+1 and all the bit lines BL0, BL1, . . . , BLm are set at 1.2 V with respect to the reference potential applied to the lower part of the substrate, and the word lines WL0, . . . , WLn, WLn+1 are held at zero potential. The word storage function is thus obtained.

Starting from this state, one or more stored word(s), or possibly all the words stored in the memory array, may be erased by applying an electrical potential of zero to the source line(s) which correspond(s) to the storage location(s) of this(these) word(s). The electrical potentials of the other lines of the memory array are kept the same. Consequently, the source lines constitute the means for selecting the words to be erased.

It is assumed that all the words stored in the memory array have thus been erased, and that the memory array has been brought back into a retention state. All the source lines SL0, . . . , SLn, SLn+1 and all the bit lines BL0, BL1, . . . , BLm are therefore again held at 1.2 V. All the word lines WL0, . . . , WLn, WLn+1 are held at 0 V. All the DRAM elements therefore store the binary value 0. In order to write the binary value 1 into a given capacitor-less DRAM element, the bit line of the column to which this element belongs is set at 2.5 V while the other bit lines are held at 1.2 V. Simultaneously, the source line and the word line of the row to which the DRAM element in question belongs are set at 0 V and 1.0 V, respectively, while the other source lines and word lines of the memory array are respectively held at 1.2 V and 0 V. The binary value 1 is thus written into the DRAM element selected by the corresponding word, source and bit lines.

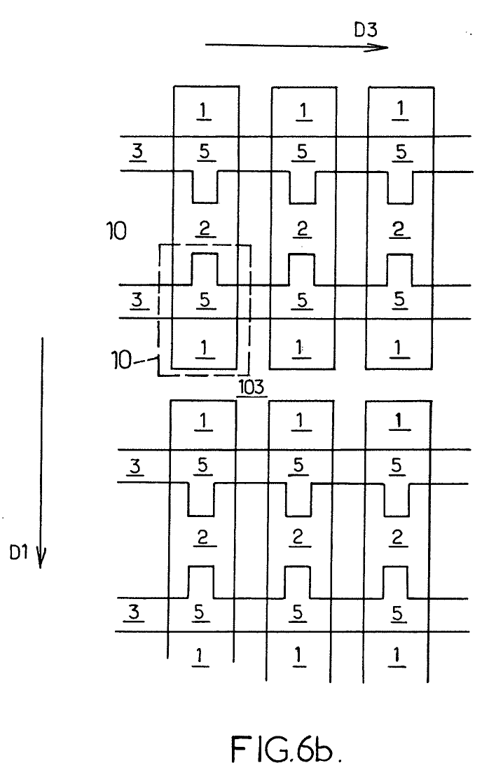

FIGS. 6a and 6b show possible configurations of memory arrays, respectively comprising DRAM elements according to the embodiments of the invention illustrated by FIGS. 2a and 2c. In order to increase the density of bits stored per unit area of substrate, each drain region 2 is shared between two DRAM elements belonging to the same column and to two adjacent rows. In other words, the rows of DRAM elements are divided up into pairs of adjacent rows, and two elements belonging to respective rows of a given pair and to the same column have the same shared drain regions 2. Write, read or erase steps carried out in one of the two DRAM elements that share one and the same drain region are then differentiated by the voltages applied to the source lines and word lines of the respective rows of the two DRAM elements.

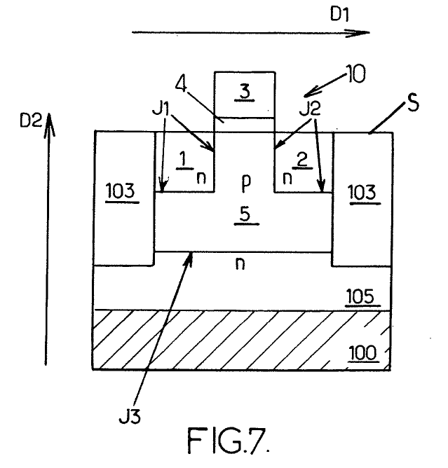

Lastly, FIG. 7 illustrates the principle of alternative embodiments of the invention. A dynamic random access memory integrated element according to the invention can also be fabricated from a bulk silicon substrate, instead of an SOI-type substrate. In other words, the isolation layer 101 is no longer present. The electrical separation between the storage region 5 and the lower conducting part 100 of the substrate is provided in the form of an electrical junction J3. A buried n-doped semiconductor region 105 is inserted below the p-doped storage region 5 with respect to the direction D2. An electrical potential barrier, associated with the junction J3, then prevents the holes h⁺ contained within the region 5 from flowing towards the part 100 of the substrate. For this purpose, a positive electrical potential, which can be in the range from 0 V to 1.2 V, can be applied to the region 105. In this case, the lateral barrier 103 of insulating material has a thickness in the direction D2 greater than that of the source I and drain 2 regions. As an example, the thickness of the barrier 103 can be around 400 nm, whereas the regions 1 and 2 can each have a thickness of around 150 nm. Given that the region 105 has a doping of the same type as the regions 1 and 2, it is preferably separated from the latter by a lower part of the region 5, in order to electrically isolate the source 1 and drain 2 regions with respect to the part 100 of the substrate. In this case, the difference between the respective widths of the junctions J1 and J2 in the direction D3 is no longer the only relevant parameter of the invention. The difference between the respective areas of the junctions J1 and J2 needs to be considered, taking into account, in these areas, faces that are parallel to the surface S of the substrate, which form the respective limits of the source region 1 and of the drain region 2 against the region 5 on an opposite side to the surface S in the direction D2.

A person skilled in the art will understand that shapes identical to those of the regions 1, 2, 3 and 5 described in relation to FIGS. 2a-2d in the case of a substrate of the SOI type may also be used for an embodiment of the invention using a bulk silicon substrate.

Furthermore, the operation of such a DRAM element fabricated from a bulk silicon substrate is substantially analogous to that of a DRAM element according to the invention fabricated from an SOI substrate, such as is described above.

Finally, it will be understood that the preceding embodiments may be modified in various ways, while at the same time conserving at least some of the advantages of the invention. In particular, the n-type or p-type dopings of the various regions of the DRAM element transistor can be reversed. The signs of the electrical potentials that are characteristic of the DRAM element operation are then opposite to those of the values mentioned in the above description.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A dynamic random access memory integrated element designed to store one bit, comprising an MOS transistor disposed on a surface of a substantially planar substrate, the transistor comprising:
a source region and a drain region separated from one another and having a doping of a first type;
a region for the storage of electrical charges extending between the source and the drain regions in a first direction parallel to the substrate surface and having a doping of a second type opposite to the first type; and
a gate region extending above the storage region and being isolated from the storage region by an insulating layer;
wherein the source, drain and storage regions are electrically separated from a lower conducting part of the substrate,
and wherein a first electrical junction surface area between the source region and the storage region is smaller than a second electrical junction surface area between the drain region and the storage region.

2. The element according to claim 1, wherein the first electrical junction surface area between the source region and the storage region is smaller than the second electrical junction surface area between the drain region and the storage region by a factor greater than 1.5.

3. The element according to claim 1, wherein a first width of the electrical junction between the source region and the storage region is shorter than a second width of the electrical junction between the drain region and the storage region, the first and second widths being measured in a direction parallel to the substrate surface and perpendicular to the first direction.

4. The element according to claim 1, wherein the electrical junction between the source region and the storage region and the electrical junction between the drain region and the storage region are each substantially planar.

5. The element according to claim 4, wherein a projection of the storage region into a plane parallel to the surface of the substrate takes the form of a selected one of a T, an L, or a trapezium.

6. The element according to claim 5, wherein the gate region has a central part of the same dimensions as the storage region, in a direction parallel to the substrate surface, and two lateral parts situated on either side of a medial plane cutting the source region and the drain region in a direction perpendicular to the substrate surface, the lateral parts of the gate region having respective lengths greater than a length of the central part in the first direction, and wherein first respective sides of the central and lateral parts of the gate region on the side of the drain region are aligned, and wherein second respective sides of the central and lateral parts of the gate region on the side of the source region are connected via intermediate sloping faces.

7. The element according to claim 1, wherein the junction between the source region and the storage region is substantially planar, and in which the junction between the drain region and the storage region has at least one variation in orientation between several points of the junction.

8. The element according to claim 7, wherein the gate region has a section, in a plane parallel to the substrate surface, having a contour that overlays, on the side of the drain region, a projection of the electrical junction between the drain region and the storage region.

9. The element according to claim 7, wherein the storage region has an extension that penetrates into the drain region, having a width that is smaller than a width of a main part of the storage region, the widths being measured in a plane parallel to the substrate surface and perpendicular to the first direction.

10. The element according to claim 7, wherein the drain region has an extension that penetrates into the storage region, having a width that is smaller than a width of the storage region, the widths being measured in a plane parallel to the surface of the substrate and perpendicular to the first direction.

11. The element according to claim 1, additionally comprising a buried electrically insulating layer, disposed between the source, drain and storage regions, on the one hand, and the lower conducting part of the substrate, on the other, in a second direction perpendicular to the substrate surface.

12. The element according to claim 11, wherein the buried electrically insulating layer has a thickness in the range between 25 and 400 nanometers in the second direction.

13. The element according to claim 1 1, further comprising a lateral barrier of insulating material disposed within the substrate on either side of the transistor in a direction parallel to the substrate surface, the lateral barrier extending in depth into the substrate at least as far as the buried electrically insulating layer.

14. The element according to claim 11, wherein the storage region has a depletion region that is thinner, in the second direction, than the storage region during an operation of the element.

15. The element according to claim 1, further comprising a buried electrical junction disposed between the source, drain and storage regions, on the one hand, and the lower conducting part of the substrate, on the other, in a second direction perpendicular to the substrate surface.

16. The element according to claim 15, further comprising a lateral barrier of insulating material disposed within the substrate on either side of the transistor in a direction parallel to the substrate surface, the lateral barrier extending depth-wise into the substrate at least as far as the buried electrical junction.

17. The element according to claim 15, wherein the buried electrical junction is formed between the storage region and a buried semiconductor region having a doping of the first type, at a depth in the substrate situated beyond the limits of the source and drain regions on a side opposite to the substrate surface.

18. The element according to claim 17, further comprising means for applying an electrical bias potential to the buried conducting region.

19. A process for erasing a bit stored in a dynamic random access memory integrated element, wherein that element comprises:
a source region and a drain region separated from one another and having a doping of a first type;
a region for the storage of electrical charges extending between the source and the drain regions in a first direction parallel to the substrate surface and having a doping of a second type opposite to the first type; and
a gate region extending above the storage region and being isolated from the storage region by an insulating layer;
wherein the source, drain and storage regions are electrically separated from a lower conducting part of the substrate,
and wherein a first electrical junction surface area between the source region and the storage region is smaller than a second electrical junction surface area between the drain region and the storage region;
the process comprising applying respective electrical potentials to the source region, the drain region and the gate region designed to make the drain region exert a repulsive force on electrical charges contained in the storage volume in order to evacuate the electrical charges via the source region, while maintaining the transistor simultaneously in the off state.

20. The process according to claim 19, in which the absolute difference between the respective electrical potentials of the drain region and of the source region is greater than or equal to 1.2 V at one given moment at least during the erase operation.

21. A memory array comprising dynamic random access memory integrated elements, each element comprising:
a source region and a drain region separated from one another and having a doping of a first type;
a region for the storage of electrical charges extending between the source and the drain regions in a first direction parallel to the substrate surface and having a doping of a second type opposite to the first type; and
a gate region extending above the storage region and being isolated from the storage region by an insulating layer;
wherein the source, drain and storage regions are electrically separated from a lower conducting part of the substrate,
and wherein a first electrical junction surface area between the source region and the storage region is smaller than a second electrical junction surface area between the drain region and the storage region;
and wherein the elements are disposed according to a matrix configuration on the surface of the substrate common to the elements.

22. The memory array according to claim 21, wherein the matrix configuration comprises rows and columns of dynamic random access memory integrated elements, the source regions and the gate regions of the elements of each row being respectively connected to one and the same source line and to one and the same word line assigned to the row, and wherein the drain regions of the memory elements of each column are connected to one and the same bit line assigned to the column, the rows of elements being divided up into pairs of adjacent rows, and two elements belonging to respective rows of the same pair and to the same column having shared drain regions.

23. A process for erasing a memory array comprising dynamic random access memory integrated elements, each element comprising:
a source region and a drain region separated from one another and having a doping of a first type;
a region for the storage of electrical charges extending between the source and the drain regions in a first direction parallel to the substrate surface and having a doping of a second type opposite to the first type; and
a gate region extending above the storage region and being isolated from the storage region by an insulating layer;
wherein the source, drain and storage regions are electrically separated from a lower conducting part of the substrate,
and wherein a first electrical junction surface area between the source region and the storage region is smaller than a second electrical junction surface area between the drain region and the storage region;
and wherein the elements are disposed according to a matrix configuration on the surface of the substrate common to the elements;
the process comprising respectively applying a first and a second electrical potential to the source line and to the word line, assigned to a row of memory elements containing the stored word, the first and second electrical potentials being chosen so as to put each memory element transistor of the row into an off state, and applying a third electrical potential to all of the bit lines such that the first and third electrical potentials cause, within each memory element of the row, an evacuation of charges present in the storage region towards the source region.

24. A dynamic random access memory integrated transistor element, comprising:
a source region and a drain region separated from each other by a charge storage region, the source region and charge storage region forming a first electrical junction and the drain region and charge storage region forming a second electrical junction, and wherein a surface area of the first electrical junction is smaller than a surface area of the second electrical junction.

25. The element of claim 24 wherein a first width of the first electrical junction is shorter than a second width of the second electrical junction.

26. The element of claim 24, wherein a projection of the storage region into a plane parallel to a top surface of the source region, drain region and charge storage region has substantially a T shape.

27. The element of claim 24, wherein a projection of the storage region into a plane parallel to a top surface of the source region, drain region and charge storage region has substantially an L shape.

28. The element of claim 24, wherein a projection of the storage region into a plane parallel to a top surface of the source region, drain region and charge storage region has substantially a C shape.

29. The element of claim 24, wherein a projection of the storage region into a plane parallel to a top surface of the source region, drain region and charge storage region has substantially a trapezoidal shape.

30. The element of claim 24 further including a gate region overlying at least the charge storage region, wherein the gate region has a central part having substantially the same size and shape as the charge storage region, in a direction parallel to a top surface of the source region, drain region and charge storage region.
